(19) United States
(12) Patent Application Publication
(10) Pub. No.: US 2024/0053959 A1
(43) Pub. Date: Feb. 15, 2024

(54) AUTOMATIC QUANTIZATION OF A FLOATING POINT MODEL

(71) Applicant: Snap Inc., Santa Monica, CA (US)

(72) Inventors: Denys Makoviichuk, Marina Del Rey, CA (US); Jiazhuo Wang, Santa Monica, CA (US); Yang Wen, San Jose, CA (US)

(21) Appl. No.: 18/331,660

(22) Filed: Jun. 8, 2023

Related U.S. Application Data
(60) Provisional application No. 63/397,172, filed on Aug. 11, 2022.

(51) Int. Cl. G06F 7/483

(52) U.S. Cl. CPC G06F 7/483

(57) ABSTRACT

Aspects of the present disclosure involve a system comprising a computer-readable storage medium storing a program and method for automatic quantization of a floating point model. The program and method provide for providing a floating point model to an automatic quantization library, the floating point model being configured to represent a neural network, and the automatic quantization library being configured to generate a first quantized model based on the floating point model; providing a function to the automatic quantization library, the function being configured to run a forward pass on a given dataset for the floating point model; causing the automatic quantization library to generate the first quantized model based on the floating point model; causing the automatic quantization library to calibrate the first quantized model by running the first quantized model on the function; and converting the calibrated first quantized model to a second quantized model.

### TECHNICAL FIELD

The present disclosure relates generally to neural networks, including automatic quantization of a floating point model representing a neural network.

### BACKGROUND

Edge devices such as mobile phones and wearable devices have limited computing power and memory.

### BRIEF DESCRIPTION OF TILE SEVERAL VIEWS OF THE DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. Some non-limiting examples are illustrated in the figures of the accompanying drawings in which:

FIG. 1 is a diagrammatic representation of a networked environment in which the present disclosure may be deployed, according to some examples.

FIG. 2 is a diagrammatic representation of a messaging system, according to some examples, that has both client-side and server-side functionality.

FIG. 3 is a diagrammatic representation of a data structure as maintained in a database, according to some examples.

FIG. 4 is a diagrammatic representation of a message, according to some examples.

FIG. 5 illustrates an automatic quantization system configured for automatic quantization of a floating point model representing a neural network, according to some example embodiments.

FIG. 6 illustrates an example of an automatic quantization library usable by an automatic quantization system, according to some example embodiments.

FIG. 7 is a flowchart illustrating a process for automatic quantization of a floating point model representing a neural network, in accordance with some examples.

FIG. 8 is a diagrammatic representation of a machine in the form of a computer system within which a set of instructions may be executed to cause the machine to perform any one or more of the methodologies discussed herein, according to some examples.

FIG. 9 is a block diagram showing a software architecture within which examples may be implemented.

### DETAILED DESCRIPTION

Edge devices such as mobile phones and wearable devices have limited computing power and memory. Optimization is used to run deep neural networks on edge devices. One of the optimization techniques is quantization. For example, deep neural networks are usually represented by 32-bit floating point numbers, and quantization reduces the precision to q-bit integers, where the value of q can be for example, 16, 8, and 2.

After quantization, it is possible to achieve lower latency, smaller model size, and lower energy consumption. It is also possible to maintain the output quality of the neural network with minimal loss of accuracy.

The disclosed embodiments provide a system configured to automatically quantize a trained floating point model for developer(s) of a neural network. For example, the developer(s) correspond to internal developers and/or to external developers of a neural network model, for use by an application (e.g., a messaging application). The system employs an automatic quantization library configured to parse and analyze a computational graph of a given floating point model (e.g., which uses 32-bit floating point values), and to insert and replace nodes in the computational graph to construct a first quantized model. In addition, the system causes the automatic quantization library to calibrate the first quantized model by running a user-provided function on the first quantized model. The user-provided function corresponds to a forward pass on a given dataset for the quantized model. For example, the calibrated first quantized model uses 32-bit floating point values and also includes quantization statistics. The system further provides for converting the calibrated first quantized model to a second quantized model (e.g., using 8-bit fixed point values).

Thus, the system facilitates the quantization of floating point models for developer(s), such that the developer(s) are not required to manually construct quantized models. Manual construction tends to be error-prone, and is more time consuming. Moreover, the system reduces computational resources/processing power for an application (e.g., a messaging application) running on an edge device (e.g., mobile device, wearable device, and the like), while maintaining accuracy of neural networks used by the application.

Networked Computing Environment

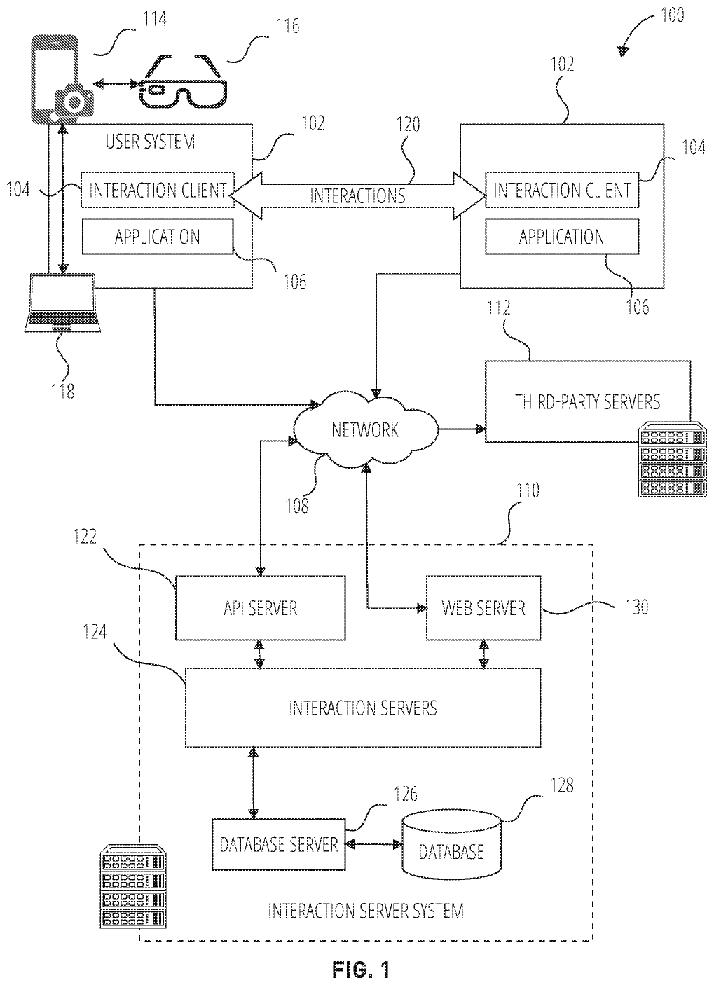

FIG. 1 is a block diagram showing an example interaction system 100 for facilitating interactions (e.g., exchanging text messages, conducting text audio and video calls, or playing games) over a network. The interaction system 100 includes multiple client systems 102, each which hosts multiple applications, including an interaction client 104 and other applications 106. Each interaction client 104 is communicatively coupled, via one or more communication networks including a network 108 (e.g., the Internet), to other instances of the interaction client 104 (e.g., hosted on respective other user systems 102), an interaction server system 110 and third-party servers 112). An interaction client 104 can also communicate with locally hosted applications 106 using Applications Program Interfaces (APIs).

Each user system 102 may include multiple user devices, such as a mobile device 114, head-wearable apparatus 116, and a computer client device 118 that are communicatively connected to exchange data and messages.

An interaction client 104 interacts with other interaction clients 104 and with the interaction server system 110 via the network 108. The data exchanged between the interaction clients 104 (e.g., interactions 120) and between the interaction clients 104 and the interaction server system 110 includes functions (e.g., commands to invoke functions) and payload data (e.g., text, audio, video, or other multimedia data).

The interaction server system 110 provides server-side functionality via the network 108 to the interaction clients 104. While certain functions of the interaction system 100 are described herein as being performed by either an interaction client 104 or by the interaction server system 110, the location of certain functionality either within the interaction client 104 or the interaction server system 110 may be a design choice. For example, it may be technically preferable to initially deploy particular technology and functionality within the interaction server system 110 but to later migrate this technology and functionality to the interaction client 104 where a user system 102 has sufficient processing capacity.

The interaction server system 110 supports various services and operations that are provided to the interaction clients 104. Such operations include transmitting data to, receiving data from, and processing data generated by the interaction clients 104. This data may include message content, client device information, geolocation information, media augmentation and overlays, message content persistence conditions, entity relationship information, and live event information. Data exchanges within the interaction system 100 are invoked and controlled through functions available via user interfaces (Ills) of the interaction clients 104.

Turning now specifically to the interaction server system 110, an Application Program Interface (API) server 122 is coupled to and provides programmatic interfaces to interaction servers 124, making the functions of the interaction servers 124 accessible to interaction clients 104, other applications 106 and third-party server 112. The interaction servers 124 are communicatively coupled to a database server 126, facilitating access to a database 128 that stores data associated with interactions processed by the interaction servers 124. Similarly, a web server 130 is coupled to the interaction servers 124 and provides web-based interfaces to the interaction servers 124. To this end, the web server 130 processes incoming network requests over the Hypertext Transfer Protocol (HTTP) and several other related protocols.

The Application Program Interface (API) server 122 receives and transmits interaction data (e.g., commands and message payloads) between the interaction servers 124 and the client systems 102 (and, for example, interaction clients 104 and other application 106) and the third-party server 112. Specifically, the Application Program Interface (API) server 122 provides a set of interfaces (e.g., routines and protocols) that can be called or queried by the interaction client 104 and other applications 106 to invoke functionality of the interaction servers 124. The Application Program Interface (API) server 122 exposes various functions supported by the interaction servers 124, including account registration; login functionality; the sending of interaction data, via the interaction servers 124, from a particular interaction client 104 to another interaction client 104; the communication of media files (e.g., images or video) from an interaction client 104 to the interaction servers 124; the settings of a collection of media data (e.g., a story); the retrieval of a list of friends of a user of a user system 102; the retrieval of messages and content; the addition and deletion of entities (e.g., friends) to an entity graph; the location of friends within an entity graph; and opening an application event (e.g., relating to the interaction client 104).

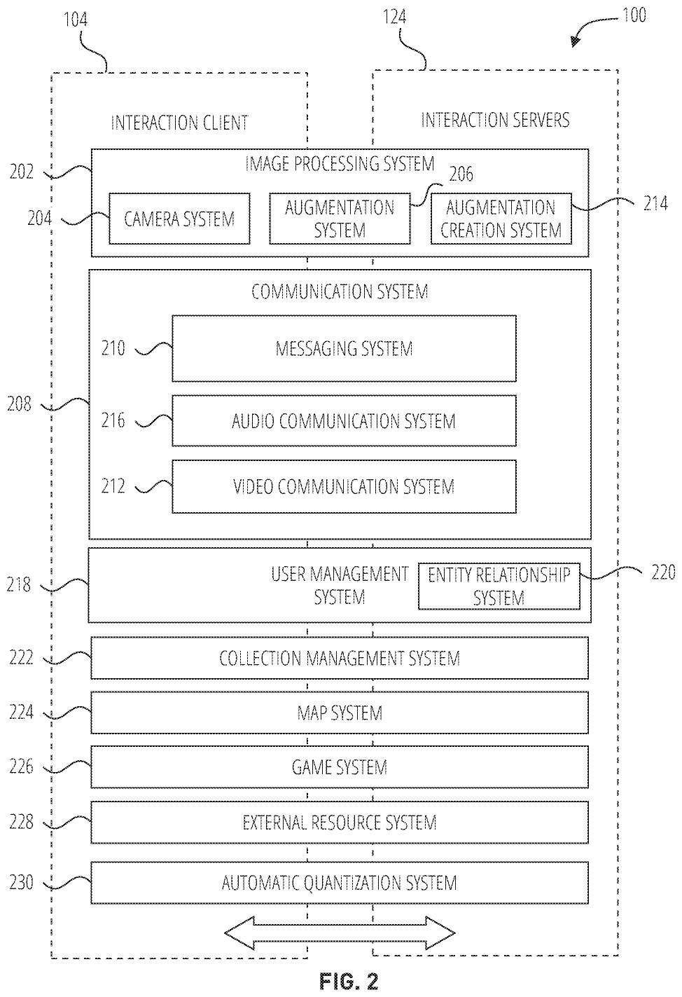

The interaction servers 124 host multiple systems and subsystems, described below with reference to FIG. 2.

System Architecture

FIG. 2 is a block diagram illustrating further details regarding the interaction system 100, according to some examples. Specifically, the interaction system 100 is shown to comprise the interaction client 104 and the interaction servers 124. The interaction system 100 embodies multiple subsystems, which are supported on the client-side by the interaction client 104 and on the server-side by the interaction servers 124: Example subsystems are discussed below,

An image processing system 202 provides various functions that enable a user to capture and augment (e.g., annotate or otherwise modify or edit) media content associated with a message.

A camera system 204 includes control software (e.g., in a camera application) that interacts with and controls hardware camera hardware (e.g., directly or via operating system controls) of the user system 102 to modify and augment real-time images captured and displayed via the interaction client 104.

The augmentation system 206 provides functions related to the generation and publishing of augmentations (e.g., media overlays) for images captured in real-time by cameras of the user system 102 or retrieved from memory of the user system 102. For example, the augmentation system 206 operatively selects, presents, and displays media overlays (e.g., an image filter or an image lens) to the interaction client 104 for the augmentation of real-time images received via the camera system 204 or stored images retrieved from memory of the user system 102. These augmentations are selected by the augmentation system 206 and presented to a user of an interaction client 104, based on a number of inputs and data, such as for example:
Geolocation of the user system 102; and
Entity relationship information of the user of the user system 102.

An augmentation may include audio and visual content and visual effects. Examples of audio and visual content include pictures, texts, logos, animations, and sound effects. An example of a visual effect includes color overlaying. The audio and visual content or the visual effects can be applied to a media content item (e.g., a photo or video) at user system 102 for communication in a message, or applied to video content, such as a video content stream or feed transmitted from an interaction client 104. As such, the image processing system 202 may interact with, and support, the various subsystems of the communication system 208, such as the messaging system 210 and the video communication system 212.

A media overlay may include text or image data that can be overlaid on top of a photograph taken by the user system 102 or a video stream produced by the user system 102. In some examples, the media overlay may be a location overlay (e.g., Venice beach), a name of a live event, or a name of a merchant overlay (e.g., Beach Coffee House). In further examples, the image processing system 202 uses the geolocation of the user system 102 to identify a media overlay that includes the name of a merchant at the geolocation of the user system 102. The media overlay may include other indicia associated with the merchant. The media overlays may be stored in the databases 128 and accessed through the database server 126.

The image processing system 202 provides a user-based publication platform that enables users to select a geolocation on a map and upload content associated with the selected geolocation. The user may also specify circumstances under which a particular media overlay should be offered to other users. The image processing system 202 generates a media overlay that includes the uploaded content and associates the uploaded content with the selected geolocation.

The augmentation creation system 214 supports augmented reality developer platforms and includes an application for content creators (e.g., artists and developers) to create and publish augmentations (e.g., augmented reality experiences) of the interaction client 104. The augmentation creation system 214 provides a library of built-in features and tools to content creators including, for example custom shaders, tracking technology, and templates.

In some examples, the augmentation creation system 214 provides a merchant-based publication platform that enables merchants to select a particular augmentation associated with a geolocation via a bidding process. For example, the augmentation creation system 214 associates a media overlay of the highest bidding merchant with a corresponding geolocation for a predefined amount of time.

A communication system 208 is responsible for enabling and processing multiple forms of communication and interaction within the interaction system 100 and includes a messaging system 210, an audio communication system 216, and a video communication system 212. The messaging system 210 is responsible for enforcing the temporary or time-limited access to content by the interaction clients 104. The audio communication system 216 enables and supports audio communications (e.g., real-time audio chat) between multiple interaction clients 104. Similarly, the video communication system 212 enables and supports video communications (e.g., real-time video chat) between multiple interaction clients 104.

A user management system 218 is operationally responsible for the management of user data and profiles, and includes an entity relationship system 220 that maintains information regarding relationships between users of the interaction system 100.

A collection management system 222 is operationally responsible for managing sets or collections of media (e.g., collections of text, image video, and audio data). A collection of content (e.g., messages, including images, video, text, and audio) may be organized into an “event gallery” or an “event story.” Such a collection may be made available for a specified time period, such as the duration of an event to which the content relates. For example, content relating to a music concert may be made available as a “story” for the duration of that music concert. The collection management system 222 may also be responsible for publishing an icon that provides notification of a particular collection to the user interface of the interaction client 104. The collection management system 222 includes a curation function that allows a collection manager to manage and curate a particular collection of content. For example, the curation interface enables an event organizer to curate a collection of content relating to a specific event (e.g., delete inappropriate content or redundant messages). Additionally, the collection management system 222 employs machine vision (or image recognition technology) and content rules to curate a content collection automatically. In certain examples, compensation may be paid to a user to include user-generated content into a collection. In such cases, the collection management system 222 operates to automatically make payments to such users to use their content.

A map system 224 provides various geographic location functions and supports the presentation of map-based media content and messages by the interaction client 104. For example, the map system 224 enables the display of user icons or avatars (e.g., stored in profile data 302) on a map to indicate a current or past location of “friends” of a user, as well as media content (e.g., collections of messages including photographs and videos) generated by such friends, within the context of a map. For example, a message posted by a user to the interaction system 100 from a specific geographic location may be displayed within the context of a map at that particular location to “friends” of a specific user on a map interface of the interaction client 104, A user can furthermore share his or her location and status information (e.g., using an appropriate status avatar) with other users of the interaction system 100 via the interaction client 104, with this location and status information being similarly displayed within the context of a map interface of the interaction client 104 to selected users.

A game system 226 provides various gaming functions within the context of the interaction client 104. The interaction client 104 provides a game interface providing a list of available games that can be launched by a user within the context of the interaction client 104 and played with other users of the interaction system 100. The interaction system 100 further enables a particular user to invite other users to participate in the play of a specific game by issuing invitations to such other users from the interaction client 104. The interaction client 104 also supports audio, video, and text messaging (e.g., chats) within the context of gameplay, provides a leaderboard for the games, and also supports the provision of in-game rewards (e.g., coins and items).

An external resource system 228 provides an interface for the interaction client 104 to communicate with remote servers (e.g., third-party servers 112) to launch or access external resources, i.e., applications or applets. Each third-party server 112 hosts, for example, a markup language (e.g., HTML5) based application or a small-scale version of an application (e.g., game, utility, payment, or ride-sharing application). The interaction client 104 may launch a web-based resource (e.g., application) by accessing the HTML5 file from the third-party servers 112 associated with the web-based resource. Applications hosted by third-party servers 112 are programmed in JavaScript leveraging a Software Development Kit (SDK) provided by the interaction servers 124. The SDK, includes Application Programming Interfaces (APIs) with functions that can be called or invoked by the web-based application. The interaction servers 124 host a JavaScript library that provides a given external resource access to specific user data of the interaction client 104. HTML5 is an example of technology for programming games, but applications and resources programmed based on other technologies can be used.

To integrate the functions of the SDK into the web-based resource, the SDK is downloaded by the third-party server 112 from the interaction servers 124 or is otherwise received by the third-party server 112. Once downloaded or received, the SDK is included as part of the application code of a web-based external resource. The code of the web-based resource can then call or invoke certain functions of the SDK to integrate features of the interaction client 104 into the web-based resource.

The SDK stored on the interaction server system 110 effectively provides the bridge between an external resource (e.g., applications 106 or applets) and the interaction client 104. This gives the user a seamless experience of communicating with other users on the interaction client 104 while also preserving the look and feel of the interaction client 104. To bridge communications between an external resource and an interaction client 104, the SDK facilitates communication between third-party servers 112 and the interaction client 104. A WebViewJavaScriptBridge running on a user system 102 establishes two one-way communication channels between an external resource and the interaction client 104. Messages are sent between the external resource and the interaction client 104 via these communication channels asynchronously. Each SDK function invocation is sent as a message and callback. Each SDK function is implemented by constructing a unique callback identifier and sending a message with that callback identifier.

By using the SDK, not all information from the interaction client 104 is shared with third-party servers 112. The SDK limits which information is shared based on the needs of the external resource. Each third-party server 112 provides an HTML5 file corresponding to the web-based external resource to interaction servers 124. The interaction servers 124 can add a visual representation (such as a box art or other graphic) of the web-based external resource in the interaction client 104. Once the user selects the visual representation or instructs the interaction client 104 through a GUI of the interaction client 104 to access features of the web-based external resource, the interaction client 104 obtains the HTML5 file and instantiates the resources to access the features of the web-based external resource.

The interaction client 104 presents a graphical user interface (e.g., a landing page or title screen) for an external resource. During, before, or after presenting the landing page or title screen, the interaction client 104 determines whether the launched external resource has been previously authorized to access user data of the interaction client 104. In response to determining that the launched external resource has been previously authorized to access user data of the interaction client 104, the interaction client 104 presents another graphical user interface of the external resource that includes functions and features of the external resource. In response to determining that the launched external resource has not been previously authorized to access user data of the interaction client 104, after a threshold period of time (e.g., 3 seconds) of displaying the landing page or title screen of the external resource, the interaction client 104 slides up (e.g., animates a menu as surfacing from a bottom of the screen to a middle or other portion of the screen) a menu for authorizing the external resource to access the user data. The menu identifies the type of user data that the external resource will be authorized to use. In response to receiving a user selection of an accept option, the interaction client 104 adds the external resource to a list of authorized external resources and allows the external resource to access user data from the interaction client 104. The external resource is authorized by the interaction client 104 to access the user data under an OAuth 2 framework.

The interaction client 104 controls the type of user data that is shared with external resources based on the type of external resource being authorized. For example, external resources that include full-scale applications (e.g., an application 106) are provided with access to a first type of user data (e.g., two-dimensional avatars of users with or without different avatar characteristics). As another example, external resources that include small-scale versions of applications (e.g., web-based versions of applications) are provided with access to a second type of user data (e.g., payment information, two-dimensional avatars of users, three-dimensional avatars of users, and avatars with various avatar characteristics). Avatar characteristics include different ways to customize a look and feel of an avatar, such as different poses, facial features, clothing, and so forth.

The automatic quantization system 230 implements various functions for automatic quantization of a floating point model, for example, with respect to the interaction system 100. In example embodiments, a floating point model represents a neural network. As described herein, a neural network typically includes a series of interconnected nodes (or “neurons”) in a series of layers. Each neuron has its own weight, bias, and activation function associated with it. The “activation” for a given neuron determines how active that neuron will be. The activation of a neuron is based on both its weight and bias values, as well as the activation function used. The weights and biases are parameters that get tuned during training of the neural network, which also results in tuning the neuron's activation.

The weights, biases, and activations are stored in memory by a neural network. For example, the weights, biases, and activations are represented as 32-bit floating point values. This allows for a high level of accuracy for the neural network.

The automatic quantization system 230 is configured to perform automatic quantization with respect to floating point models (neural networks represented by floating point values). As described herein, quantization is the process of reducing the precision of the weights, biases, and activations to consume less memory.

By way of nonlimiting example, the automatic quantization system 230 is configured to perform quantization of a neural network, represented by 32-bit floating point numbers. Such quantization reduces the precision to q-bit integers (e.g., where q is 16, 8, and 2), After quantization, it is possible to achieve lower latency, smaller model size, and lower energy consumption. It is also possible to maintain the output quality of the neural network with minimal loss of accuracy. In example embodiments, the automatic quantization system 230 provides an automatic quantization library, which is usable by developer(s) to quantize floating point models, for deployment to multiple devices (e.g., user systems 102) running an application (e.g., the interaction client 104).

Data Architecture

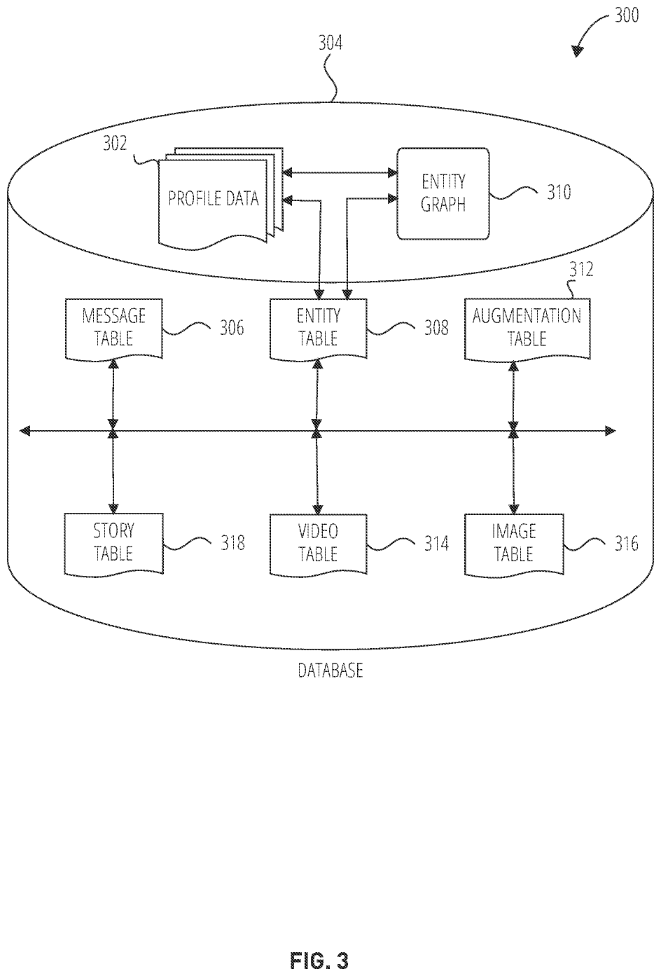

FIG. 3 is a schematic diagram illustrating data structures 300, which may be stored in the database 304 of the interaction server system 110, according to certain examples. While the content of the database 304 is shown to comprise multiple tables, it will be appreciated that the data could be stored in other types of data structures (e.g., as an object-oriented database).

The database 304 includes message data stored within a message table 306. This message data includes, for any particular message, at least message sender data, message recipient (or receiver) data, and a payload. Further details regarding information that may be included in a message, and included within the message data stored in the message table 306, are described below with reference to FIG. 3.

An entity table 308 stores entity data, and is linked (e.g., referentially) to an entity graph 310 and profile data 302, Entities for which records are maintained within the entity table 308 may include individuals, corporate entities, organizations, objects, places, events, and so forth. Regardless of entity type, any entity regarding which the interaction server system 110 stores data may be a recognized entity. Each entity is provided with a unique identifier, as well as an entity type identifier (not shown).

The entity graph 310 stores information regarding relationships and associations between entities. Such relationships may be social, professional (e.g., work at a common corporation or organization), interest-based, or activity-based, merely for example. Certain relationships between entities may be unidirectional, such as a subscription by an individual user to digital content of a commercial or publishing user (e.g., a newspaper or other digital media outlet, or a brand). Other relationships may be bidirectional, such as a “friend” relationship between individual users of the interaction system 100.

Certain permissions and relationships may be attached to each relationship, and also to each direction of a relationship. For example, a bidirectional relationship (e.g., a friend relationship between individual users) may include authorization for the publication of digital content items between the individual users, but may impose certain restrictions or filters on the publication of such digital content items (e.g., based on content characteristics, location data or time of day data). Similarly, a subscription relationship between an individual user and a commercial user may impose different degrees of restrictions on the publication of digital content from the commercial user to the individual user, and may significantly restrict or block the publication of digital content from the individual user to the commercial user. A particular user, as an example of an entity, may record certain restrictions (e.g., by way of privacy settings) in a record for that entity within the entity table 308. Such privacy settings may be applied to all types of relationships within the context of the interaction system 100, or may selectively be applied to certain types of relationships.

The profile data 302 stores multiple types of profile data about a particular entity. The profile data 302 may be selectively used and presented to other users of the interaction system 100 based on privacy settings specified by a particular entity. Where the entity is an individual, the profile data 302 includes, for example, a user name, telephone number, address, settings (e.g., notification and privacy settings), as well as a user-selected avatar representation (or collection of such avatar representations). A particular user may then selectively include one or more of these avatar representations within the content of messages communicated via the interaction system 100, and on map interfaces displayed by interaction clients 104 to other users. The collection of avatar representations may include “status avatars,” which present a graphical representation of a status or activity that the user may select to communicate at a particular time.

Where the entity is a group, the profile data 302 for the group may similarly include one or more avatar representations associated with the group, in addition to the group name, members, and various settings (e.g., notifications) for the relevant group.

The database 304 also stores augmentation data, such as overlays or filters, in an augmentation table 312. The augmentation data is associated with and applied to videos (for which data is stored in a video table 314) and images (for which data is stored in an image table 316).

Filters, in some examples, are overlays that are displayed as overlaid on an image or video during presentation to a recipient user. Filters may be of various types, including user-selected filters from a set of filters presented to a sending user by the interaction client 104 when the sending user is composing a message. Other types of titters include geolocation filters (also known as geo-filters), which may be presented to a sending user based on geographic location. For example, geolocation filters specific to a neighborhood or special location may be presented within a user interface by the interaction client 104, based on geolocation information determined by a Global Positioning System (GPS) unit of the user system 102.

Another type of filter is a data filter, which may be selectively presented to a sending user by the interaction client 104 based on other inputs or information gathered by the user system 102 during the message creation process. Examples of data filters include current temperature at a specific location, a current speed at which a sending user is traveling, battery life for a user system 102, or the current time.

Other augmentation data that may be stored within the image table 316 includes augmented reality content items (e.g., corresponding to applying “lenses” or augmented reality experiences). An augmented reality content item may be a real-time special effect and sound that may be added to an image or a video.

A story table 318 stores data regarding collections of messages and associated image, video, or audio data, which are compiled into a collection (e.g., a story or a gallery). The creation of a particular collection may be initiated by a particular user (e.g., each user for which a record is maintained in the entity table 308), A user may create a “personal story” in the form of a collection of content that has been created and sent/broadcast by that user. To this end, the user interface of the interaction client 104 may include an icon that is user-selectable to enable a sending user to add specific content to his or her personal story.

A collection may also constitute a “live story,” which is a collection of content from multiple users that is created manually, automatically, or using a combination of manual and automatic techniques. For example, a “live story” may constitute a curated stream of user-submitted content from various locations and events, Users whose client devices have location services enabled and are at a common location event at a particular time may, for example, be presented with an option, via a user interface of the interaction client 104, to contribute content to a particular live story. The live story may be identified to the user by the interaction client 104, based on his or her location. The end result is a “live story” told from a community perspective.

A further type of content collection is known as a “location story,” which enables a user whose user system 102 is located within a specific geographic location (e.g., on a college or university campus) to contribute to a particular collection. In some examples, a contribution to a location story may employ a second degree of authentication to verify that the end-user belongs to a specific organization or other entity (e.g., is a student on the university campus).

As mentioned above, the video table 314 stores video data that, in some examples, is associated with messages for which records are maintained within the message table 306. Similarly, the image table 316 stores image data associated with messages for which message data is stored in the entity table 308. The entity table 308 may associate various augmentations from the augmentation table 312 with various images and videos stored in the image table 316 and the video table 314.

Data Communications Architecture

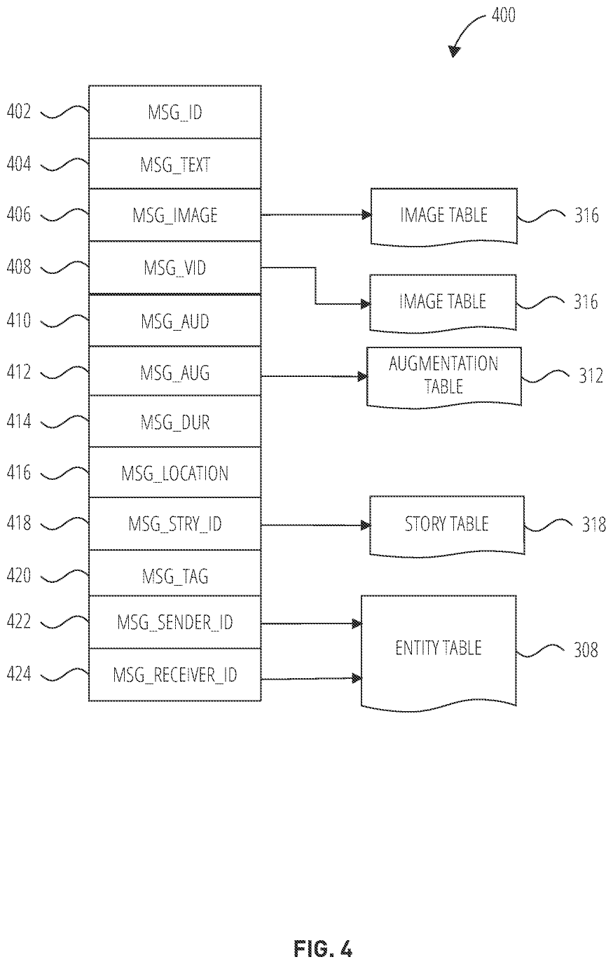

FIG. 4 is a schematic diagram illustrating a structure of a message 400, according to some examples, generated by an interaction client 104 for communication to a further interaction client 104 via the interaction servers 124. The content of a particular message 400 is used to populate the message table 306 stored within the database 304, accessible by the interaction servers 124. Similarly, the content of a message 400 is stored in memory as “in-transit” or “in-flight” data of the user system 102 or the interaction servers 124. A message 400 is shown to include the following example components:
Message identifier 402: a unique identifier that identifies the message 400.
Message text payload 404: text, to be generated by a user via a user interface of the user system 102, and that is included in the message 400.
Message image payload 406: image data, captured by a camera component of a user system 102 or retrieved from a memory component of a user system 102, and that is included in the message 400. Image data for a sent or received message 400 may be stored in the image table 316.
Message video payload 408: video data, captured by a camera component or retrieved from a memory component of the user system 102, and that is included in the message 400. Video data for a sent or received message 400 may be stored in the image table 316.
Message audio payload 410: audio data, captured by a microphone or retrieved from a memory component of the user system 102, and that is included in the message 400.
Message augmentation data 412: augmentation data (e.g., filters, stickers, or other annotations or enhancements) that represents augmentations to be applied to message image payload 406, message video payload 408, or message audio payload 410 of the message 400. Augmentation data for a sent or received message 400 may be stored in the augmentation table 312.
Message duration parameter 414: parameter value indicating, in seconds, the amount of time for which content of the message (e.g., the message image payload 406, message video payload 408, message audio payload 410) is to be presented or made accessible to a user via the interaction client 104.
Message geolocation parameter 416: geolocation data (e.g., latitudinal and longitudinal coordinates) associated with the content payload of the message. Multiple message geolocation parameter 416 values may be included in the payload, each of these parameter values being associated with respect to content items included in the content (e.g., a specific image within the message image payload 406, or a specific video in the message video payload 408),
Message story identifier 418: identifier values identifying one or more content collections (e.g., “stories” identified in the story table 318) with which a particular content item in the message image payload 406 of the message 400 is associated. For example, multiple images within the message image payload 406 may each be associated with multiple content collections using identifier values.
Message tag 420: each message 400 may be tagged with multiple tags, each of which is indicative of the subject matter of content included in the message payload. For example, where a particular image included in the message image payload 406 depicts an animal (e.g., a lion), a tag value may be included within the message tag 420 that is indicative of the relevant animal. Tag values may be generated manually, based on user input, or may be automatically generated using, for example, image recognition.
Message sender identifier 422: an identifier (e.g., a messaging system identifier, email address, or device identifier) indicative of a user of the user system 102 on which the message 400 was generated and from which the message 400 was sent.
Message receiver identifier 424: an identifier (e.g., a messaging system identifier, email address, or device identifier) indicative of a user of the user system 102 to which the message 400 is addressed.

The contents (e.g., values) of the various components of message 400 may be pointers to locations in tables within which content data values are stored. For example, an image value in the message image payload 406 may be a pointer to (or address of) a location within an image table 316. Similarly, values within the message video payload 408 may point to data stored within an image table 316, values stored within the message augmentation data 412 may point to data stored in an augmentation table 312, values stored within the message story identifier 418 may point to data stored in a story table 318, and values stored within the message sender identifier 422 and the message receiver identifier 424 may point to user records stored within an entity table 308.

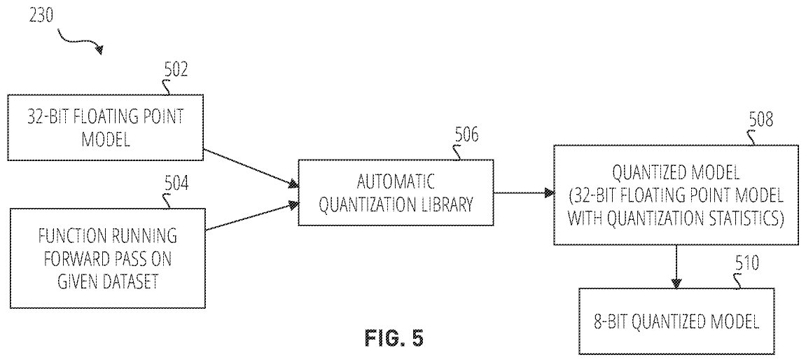

FIG. 5 illustrates an automatic quantization system 230 configured for automatic quantization of a floating point model representing a neural network, according to some example embodiments. As shown in the example of FIG. 5, the automatic quantization system 230 depicts a 32-bit floating point model 502, a function 504, an automatic quantization library 506, a quantized model 508 and an 8-bit quantized model 510. Not all of the depicted components may be used in all implementations, and example embodiments may include additional or different components than those shown in the figure. Variations in the arrangement and type of the components may be made without departing from the spirit or scope of the claims as set forth herein.

In example embodiments, the automatic quantization system 230 corresponds to a subsystem of the interaction system 100, and may be supported on the server side by the interaction server system 110. Thus, the quantization performed by the automatic quantization system 230 is implemented server side. However, it is possible for the automatic quantization system 230 to be supported, at least in part, on the client side by the interaction client 104, such that the quantization is implemented by a combination of server side and client side operations.

As described herein, the automatic quantization system 230 is configured to automatically quantize a user-provided 32-bit floating point model 502. The automatic quantization library 506 is configured to parse and analyze a computational graph of the 32-bit floating point model 502, and to insert and replace nodes in the computational graph to construct a first quantized model 508. In addition, the automatic quantization system 230 causes the automatic quantization library 506 to calibrate the first quantized model 508, by running a user-provided function 504 (a forward pass on a given dataset) on the first quantized model 508. The automatic quantization system 230 further provides for converting the calibrated quantized model 508 to a second quantized model (e.g., the 8-bit quantized model 510).

In example embodiments, the interaction system 100 is configured to employ different types of neural networks for different features offered by the interaction system 100. The 32-bit floating point model 502 represents a neural network corresponding to a respective feature. By way of non-limiting example, features implemented by the 32-bit floating point model 502 and usable by the interaction system 100 include: augmented reality (e.g., including facial recognition, object detection and the like); selecting and serving relevant and interesting video content (e.g., as provided by an administrator of the interaction system 100), content collections (e.g., stories) that are currently trending on the interaction system 100, and/or content collections (e.g., stories) covering politics, entertainment, sports and more as provided by predetermined publishers (e.g., corporate partners); returning relevant search results; and/or security architecture for detecting/flagging prohibited content.

As noted above, a neural network typically includes a series of interconnected neurons in a series of layers. Each neuron has its own weight, bias, and activation function associated with it. The activation of a neuron is based on both its weight and bias values, as well as the activation function used. The weights and biases are parameters that get tuned during training of the neural network, which also results in tuning the neuron's activation. The weights, biases, and activations are stored in memory by a neural network.

In the example of FIG. 5, the weights, biases, and activations for the 32-bit floating point model 502 are represented as 32-bit floating point values. This allows for a high level of accuracy for the neural network represented by the 32-bit floating point model 502. The automatic quantization system 230 provides for reducing the precision to 8-bit integers, corresponding to the 8-bit quantized model 510.

In example embodiments, the 32-bit floating point model 502 corresponds to a trained floating point model provided by one or more developer(s). For example, the developer(s) are internal employee(s) associated with the interaction system 100. In another example, the developer(s) are external, third-party developer(s) for neural networks usable by the interaction system 100.

In addition to generating and training the 32-bit floating point model 502, the developer(s) provide a function 504 configured to run a forward pass on a given dataset (e.g., data inputs, expected output) for a neural network. For the given data inputs, the forward pass traverses all neurons from the first layer to the last layer of the neural network in order to produce output values (e.g., predictions). The function 504 is configured to calculate network error based on comparing the output values (e.g., predictions) with the expected output.

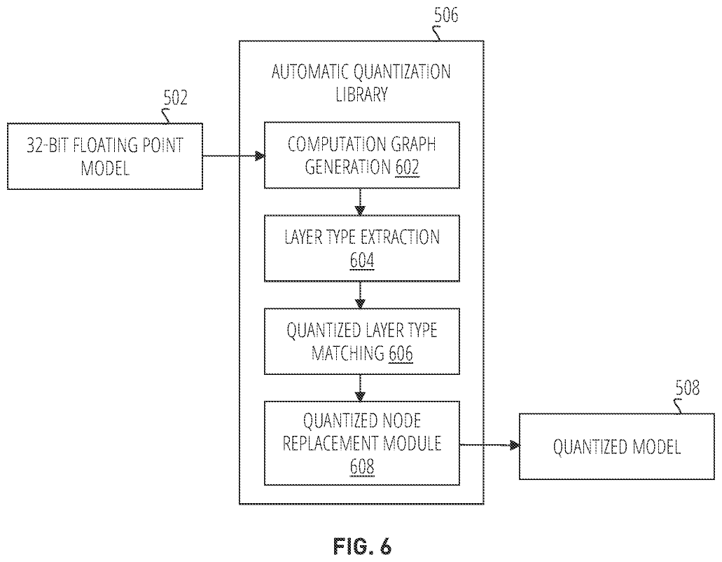

In example embodiments, the automatic quantization system 230 provides for the automatic quantization library 506 to convert the 32-bit floating point model 502 into the quantized model 508. In example embodiments, the automatic quantization library 506 is an open source library, implemented by the interaction system 100, that is accessible by the developer(s). As discussed further below with respect to FIG. 6, conversion of the 32-bit floating point model 502 to the quantized model 508 is performed by the automatic quantization library 506 in an automatic manner. In other words, the developer(s) are not required to manually construct the quantized model 508 themselves.

After converting the 32-bit floating point model 502 to the quantized model 508, the automatic quantization system 230 provides for the automatic quantization library 506 to run the user-provided function 504 with respect to the quantized model 508. In example embodiments, the function 504 traverses all neurons from the first layer to the last layer of the quantized model 508 to produce output values (e.g., predictions). Moreover, the function 504 calculates network error based on comparing the output values with expected output. In this manner, the automatic quantization library 506 provides for calibrating the quantized model 508. Such calibration corresponds with computing quantization statistics, as discussed further below with respect to FIG. 6.

The automatic quantization system 230 then provides for the developer to export the calibrated quantized model 508 to an open neural network exchange format (“onnx”) format. For example the automatic quantization system 230 provides the developer with appropriate user interfaces, in order to convert the quantized model 508 to onnx format.

As shown in FIG. 5, the automatic quantization system 230 provides for converting the quantized model 508 (in onnx format) into the 8-bit quantized model 510. In example embodiments, the automatic quantization system 230 implements an additional library, separate from the automatic quantization library 506, for performing the conversion to the 8-bit quantized model 510. For example, the additional library is a closed source library, implemented by the interaction system 100. The additional library is configured to convert from a quantized model (e.g., the quantized model 508 corresponding to a 32-bit floating point model with quantization statistics) to the 8-bit quantized model 510.

In example embodiments, the automatic quantization system 230 in configured to achieve lower latency, smaller model size, and lower energy consumption. The automatic quantization system 230 is further configured to maintain the output quality of the neural network (e.g., the 32-bit floating point model 502) with minimal loss of accuracy. In example embodiments, the automatic quantization system 230 provides the 8-bit quantized model 510 for deployment to edge devices (e.g., user systems 102 such as mobile devices, wearable devices, and the like) running an application (e.g., the interaction client 104).

FIG. 6 illustrates an example of the automatic quantization library 506 usable by the automatic quantization system 230, according to some example embodiments. As discussed above with respect to FIG. 5, the 32-bit floating point model 502 is provided as input to the automatic quantization library 506. The automatic quantization library 506 provides the quantized model 508 as output. The automatic quantization library 506 includes a computation graph generation module 602, a layer type extraction module 604, a quantized layer type matching module 606, and a quantized node replacement module 608. Not all of the depicted components may be used in all implementations, and example embodiments may include additional or different components than those shown in the figure. Variations in the arrangement and type of the components may be made without departing from the spirit or scope of the claims as set forth herein.

As shown in the example of FIG. 6, the 32-bit floating point model 502 is provided as input to the computation graph generation module 602. The computation graph generation module 602 is configured to build a computations graph based on the input 32-bit floating point model 502. In example embodiments, the automatic quantization library 506 is configured to be compatible with PyTorch® models (e.g., as opposed to TensorFlow® models). However, the automatic quantization library 506 is not limited to such, and it is possible for the automatic quantization library 506 to be compatible with other types of models.

In example embodiments, the computation graph generation module 602 performs a function call, using the PyTorch® framework. By way of non-limiting example, the computation graph generation module 602 calls the function: traced=fx.symbolic_trace(model). In this equation, model is the input (e.g., the 32-bit floating point model 502), and symbolic_trace is a function configured to which output traced, corresponding to the computation graph.

The computation graph generated by the computation graph generation module 602 is provided as input to the layer type extraction module 604. The layer type extraction module 604 is configured to traverse through each node of the computational graph, in order to extract the layer type for the node. For example, the layer type may relate one or more of: input layer, output layer, hidden layer; first, last middle layers; fully connected, convolution, deconvolution, recurrent; and/or the transfer function, the activation function, biases and/or weights associated with a given node in the layer.

The quantized layer type matching module 606 is configured to match, for each node, the layer type with a quantized layer type supported by the automatic quantization library 506. As noted above, for example, the layer type may relate one or more of: input layer, output layer, hidden layer; first, last middle layers; fully connected, convolution, deconvolution, recurrent; and/or the transfer function, the activation function, biases and/or weights associated with a given node in the layer.

For each node, the quantized node replacement module 608 is configured to construct a quantized node (corresponding to the matching quantized layer type for that node), and to replace the original node with the quantized node. The quantized model 508 corresponds to replacement of the original nodes with the quantized nodes, and is returned as output by the automatic quantization library 506.

In example aspects, the automatic quantization library 506 is not limited to fixed point arithmetic in PyTorch®. For example, the computations in the quantized model 508 are still in floating point numbers. Moreover, the quantized model 508 is configured to use either floating point arithmetic or fixed point arithmetic. In contrast, with respect to TensorFlow®, quantized models (e.g., generated by TensorFlow® Lite) use fixed point numbers in computations.

Thus, the automatic quantization library 506 is configured to parse and analyze the computational graph of the 32-bit floating point model 502, and to insert and replace nodes in computational graph to construct the corresponding quantized model 508. By virtue of the foregoing, the automatic quantization library 506 in conjunction with the automatic quantization system 230 provides for constructing a quantized model (e.g., the quantized model 508) in an automatic manner, instead of requiring manual construction from a developer. As noted above, manual construction tends to be error-prone, and is more time consuming. The quantized model 508 is then converted to the 8-bit quantized model 510. As such, the automatic quantization system 230 facilitates reduces computational resources/processing power for the interaction system 100.

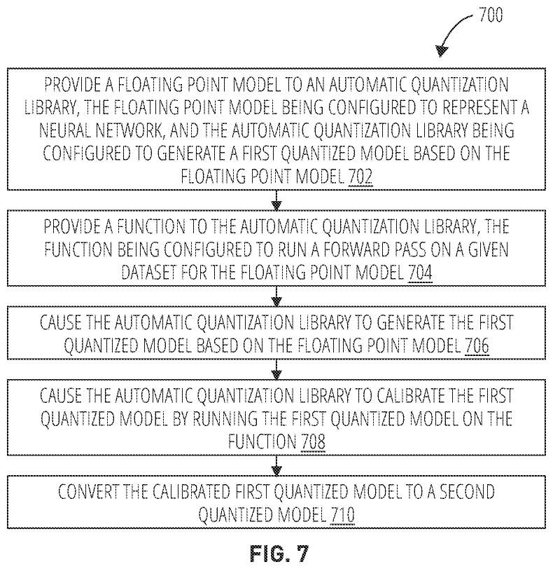

FIG. 7 is a flowchart illustrating a process 700 for automatic quantization of a floating point model representing a neural network, in accordance with some examples. For explanatory purposes, the process 700 is primarily described herein with reference to the automatic quantization system 230 of FIG. However, one or more blocks (or operations) of the process 700 may be performed by one or more other components, and/or by other suitable devices. Further for explanatory purposes, the blocks (or operations) of the process 700 are described herein as occurring in serial, or linearly. However, multiple blocks (or operations) of the process 700 may occur in parallel or concurrently. In addition, the blocks (or operations) of the process 700 need not be performed in the order shown and/or one or more blocks (or operations) of the process 700 need not be performed and/or can be replaced by other operations. The process 700 may be terminated when its operations are completed. In addition, the process 700 may correspond to a method, a procedure, an algorithm, etc.

The automatic quantization system 230 provides a floating point model to an automatic quantization library (block 702). The floating point model is configured to represent a neural network, and the automatic quantization library is configured to generate a first quantized model based on the floating point model.

The automatic quantization system 230 provides a function to the automatic quantization library (block 704). The function is configured to run a forward pass on a given dataset for the floating point model. The automatic quantization system 230 causes the automatic quantization library to generate the first quantized model based on the floating point model (block 706).

In example embodiments, the automatic quantization library is configured to generate a computational graph based on the floating point model. For each node in the computational graph, the automatic quantization library is configured to extract a layer type for the node, match the layer type to a quantized layer type supported by the automatic quantization library, and replace the node with a quantized node corresponding to the quantized layer type. In addition, the automatic quantization library is configured to provide the first quantized model as output based on replacing the nodes with the quantized nodes.

The automatic quantization system 230 causes the automatic quantization library to calibrate the first quantized model by running the first quantized model on the function (block 708). In example embodiments, the automatic quantization system 230 exports the calibrated first quantized model to an open neural network exchange format.

The automatic quantization system 230 converts the calibrated first quantized model to a second quantized model (block 710). For example, converting the calibrated first quantized model to the second quantized model is based on the open neural network exchange format of the calibrated first quantized model as exported.

In example embodiments, each of the floating point model and the first quantized model corresponds to a 32-bit floating point model. In addition, the calibrated first quantized model corresponds to a 32-bit floating point model with quantization statistics. Moreover, the second quantized model corresponds to an 8-bit quantized model.

In example embodiments, the automatic quantization system 230 provides the second quantized model to a client device (e.g., a user system 102). The second quantized model is configured to represent the neural network and to be accessible by an application (e.g., interaction client 104) running on the client device. For example, the automatic quantization library is usable by developers to quantize floating point models for storage on client devices running the application.

Machine Architecture

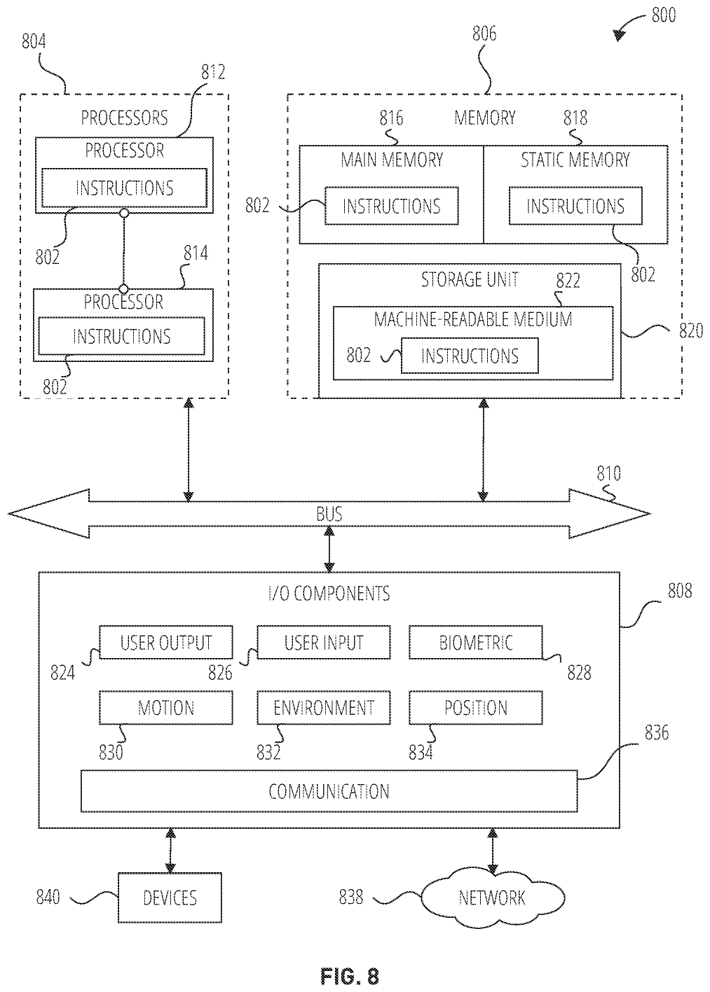

FIG. 8 is a diagrammatic representation of the machine 800 within which instructions 802 (e.g., software, a program, an application, an applet, an app, or other executable code) for causing the machine 800 to perform any one or more of the methodologies discussed herein may be executed. For example, the instructions 802 may cause the machine 800 to execute any one or more of the methods described herein. The instructions 802 transform the general, non-programmed machine 800 into a particular machine 800 programmed to carry out the described and illustrated functions in the manner described. The machine 800 may operate as a standalone device or may be coupled (e.g., networked) to other machines. In a networked deployment, the machine 800 may operate in the capacity of a server machine or a client machine in a server-client network environment, or as a peer machine in a peer-to-peer (or distributed) network environment. The machine 800 may comprise, but not be limited to, a server computer, a client computer, a personal computer (PC), a tablet computer, a laptop computer, a netbook, a set-top box (STB), a personal digital assistant (PDA), an entertainment media system, a cellular telephone, a smartphone, a mobile device, a wearable device (e.g., a smartwatch), a smart home device (e.g., a smart appliance), other smart devices, a web appliance, a network router, a network switch, a network bridge, or any machine capable of executing the instructions 802, sequentially or otherwise, that specify actions to be taken by the machine 800. Further, while a single machine 800 is illustrated, the term “machine” shall also be taken to include a collection of machines that individually or jointly execute the instructions 802 to perform any one or more of the methodologies discussed herein. The machine 800, for example, may comprise the user system 102 or any one of multiple server devices forming part of the interaction server system 110, In some examples, the machine 800 may also comprise both client and server systems, with certain operations of a particular method or algorithm being performed on the server-side and with certain operations of the particular method or algorithm being performed on the client-side.

The machine 800 may include processors 804, memory 806, and input/output 110 components 808, which may be configured to communicate with each other via a bus 810, In an example, the processors 804 (e.g., a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), an Application Specific Integrated Circuit (ASIC), a Radio-Frequency integrated Circuit (RFIC), another processor, or any suitable combination thereof) may include, for example, a processor 812 and a processor 814 that execute the instructions 802. The term “processor” is intended to include multi-core processors that may comprise two or more independent processors (sometimes referred to as “cores”) that may execute instructions contemporaneously. Although FIG. 8 shows multiple processors 804, the machine 800 may include a single processor with a single-core, a single processor with multiple cores (e.g., a multi-core processor), multiple processors with a single core, multiple processors with multiples cores, or any combination thereof.

The memory 806 includes a main memory 816, a static memory 818, and a storage unit 820, both accessible to the processors 804 via the bus 810. The main memory 806 the static memory 818, and storage unit 820 store the instructions 802 embodying any one or more of the methodologies or functions described herein. The instructions 802 may also reside, completely or partially, within the main memory 816, within the static memory 818, within machine-readable medium 822 within the storage unit 820, within at least one of the processors 804 (e.g., within the processor's cache memory), or any suitable combination thereof, during execution thereof by the machine 800.

The I/O components 808 may include a wide variety of components to receive input, provide output, produce output, transmit information, exchange information, capture measurements, and so on. The specific I/O components 808 that are included in a particular machine will depend on the type of machine. For example, portable machines such as mobile phones may include a touch input device or other such input mechanisms, while a headless server machine will likely not include such a touch input device. It will be appreciated that the I/O components 808 may include many other components that are not shown in FIG. 8. In various examples, the I/O components 808 may include user output components 824 and user input components 826. The user output components 824 may include visual components (e.g., a display such as a plasma display panel (PDP), a light-emitting diode (LED) display, a liquid crystal display (LCD), a projector, or a cathode ray tube (CRT)), acoustic components (e.g., speakers), haptic components (e.g., a vibratory motor, resistance mechanisms), other signal generators, and so forth. The user input components 826 may include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or another pointing instrument), tactile input components (e.g., a physical button, a touch screen that provides location and force of touches or touch gestures, or other tactile input components), audio input components (e.g., a microphone), and the like.

In further examples, the I/O components 808 may include biometric components 828, motion components 830, environmental components 832, or position components 834, among a wide array of other components. For example, the biometric components 828 include components to detect expressions (e.g., hand expressions, facial expressions, vocal expressions, body gestures, or eye-tracking), measure biosignals (e.g., blood pressure, heart rate, body, temperature, perspiration, or brain waves), identify a person (e.g., voice identification, retinal identification, facial identification, fingerprint identification, or electroencephalogram-based identification), and the like. Any biometric collected by the biometric components is captured and stored with only user approval and deleted on user request. Further, such biometric data may be used for very limited purposes, such as identification verification. To ensure limited and authorized use of biometric information and other personally identifiable information (PII), access to this data is restricted to authorized personnel only, if at all. Any use of biometric data may strictly be limited to identification verification purposes, and the biometric data is not shared or sold to any third party without the explicit consent of the user. In addition, appropriate technical and organizational measures are implemented to ensure the security and confidentiality of this sensitive information. The motion components 830 include acceleration sensor components (e.g., accelerometer), gravitation sensor components, rotation sensor components (e.g., gyroscope).

The environmental components 832 include, for example, one or cameras (with still image/photograph and video capabilities), illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensors (e.g., gas detection sensors to detection concentrations of hazardous gases for safety or to measure pollutants in the atmosphere), or other components that may provide indications, measurements, or signals corresponding to a surrounding physical environment.

With respect to cameras, the user system 102 may have a camera system comprising, for example, front cameras on a front surface of the user system 102 and rear cameras on a rear surface of the user system 102. The front cameras may, for example, be used to capture still images and video of a user of the user system 102 (e.g., “selfies”), which may then be augmented with augmentation data (e.g., filters) described above. The rear cameras may, for example, be used to capture still images and videos in a more traditional camera mode, with these images similarly being augmented with augmentation data. In addition to front and rear cameras, the user system 102 may also include a 360° camera for capturing 360″ photographs and videos.

Further, the camera system of the user system 102 may include dual rear cameras (e.g., a primary camera as well as a depth-sensing camera), or even triple, quad or penta rear camera configurations on the front and rear sides of the user system 102. These multiple cameras systems may include a wide camera, an ultra-wide camera, a telephoto camera, a macro camera, and a depth sensor, for example.

The position components 834 include location sensor components (e.g., a GPS receiver component), altitude sensor components (e.g., altimeters or barometers that detect air pressure from which altitude may be derived), orientation sensor components (e.g., magnetometers), and the like.

Communication may be implemented using a wide variety of technologies. The I/O components 808 further include communication components 836 operable to couple the machine 800 to a network 838 or devices 840 via respective coupling or connections. For example, the communication components 836 may include a network interface component or another suitable device to interface with the network 838. In further examples, the communication components 836 may include wired communication components, wireless communication components, cellular communication components, Near Field Communication (NIT) components, Bluetooth® components (e.g., Bluetooth® Low Energy), components, and other communication components to provide communication via other modalities. The devices 840 may be another machine or any of a wide variety of peripheral devices (e.g., a peripheral device coupled via a USB).

Moreover, the communication components 836 may detect identifiers or include components operable to detect identifiers. For example, the communication components 836 may include Radio Frequency Identification (RFID) tag reader components, NFC smart tag detection components, optical reader components (e.g., an optical sensor to detect one-dimensional bar codes such as Universal Product Code (UPC) bar code, multi-dimensional bar codes such as Quick Response (QR) code, Aztec code, Data Matrix, Dataglyph, MaxiCode, PDF417, Ultra Code, UCC RSS-2D bar code, and other optical codes), or acoustic detection components (e.g., microphones to identify tagged audio signals). In addition, a variety of information may be derived via the communication components 836, such as location via Internet Protocol (IP) geolocation, location via Wi-Fi® signal triangulation, location via detecting an NFC beacon signal that may indicate a particular location, and so forth.

The various memories (e.g., main memory 816, static memory 818, and memory of the processors 804) and storage unit 820 may store one or more sets of instructions and data structures (e.g., software) embodying or used by any one or more of the methodologies or functions described herein. These instructions the instructions 802), when executed by processors 804, cause various operations to implement the disclosed examples.

The instructions 802 may be transmitted or received over the network 838, using a transmission medium, via a network interface device (e.g., a network interface component included in the communication components 836) and using any one of several well-known transfer protocols (e.g., hypertext transfer protocol (HTTP)). Similarly, the instructions 802 may be transmitted or received using a transmission medium via a coupling (e.g., a peer-to-peer coupling) to the devices 840.

Software Architecture

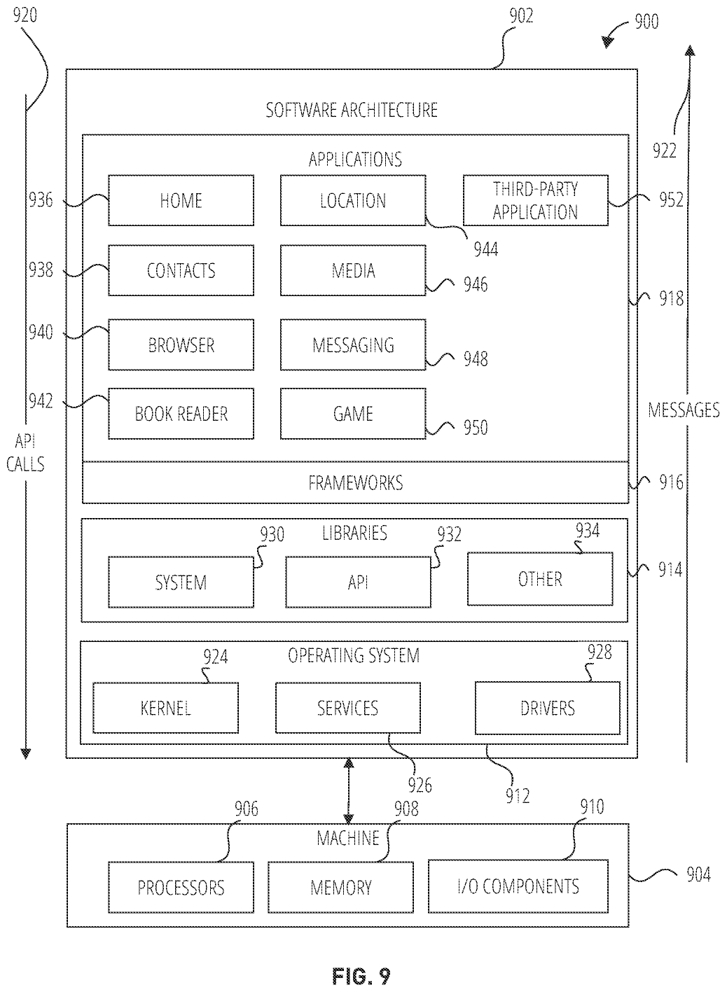

FIG. 9 is a block diagram 900 illustrating a software architecture 902, which can be installed on any one or more of the devices described herein. The software architecture 902 is supported by hardware such as a machine 904 that includes processors 906, memory 908, and I/O components 910. In this example, the software architecture 902 can be conceptualized as a stack of layers, where each layer provides a particular functionality. The software architecture 902 includes layers such as an operating system 912, libraries 914, frameworks 916, and applications 918. Operationally, the applications 918 invoke API calls 920 through the software stack and receive messages 922 in response to the API calls 920.

The operating system 912 manages hardware resources and provides common services. The operating system 912 includes, for example, a kernel 924, services 926, and drivers 928, The kernel 924 acts as an abstraction layer between the hardware and the other software layers. For example, the kernel 924 provides memory management, processor management (e.g., scheduling), component management, networking, and security settings, among other functionalities. The services 926 can provide other common services for the other software layers. The drivers 928 are responsible for controlling or interfacing with the underlying hardware. For instance, the drivers 928 can include display drivers, camera drivers, BLUETOOTH® or BLUETOOTH® Low Energy drivers, flash memory drivers, serial communication drivers (e.g., USB drivers), WI-FI® drivers, audio drivers, power management drivers, and so forth.

The libraries 914 provide a common low-level infrastructure used by the applications 918. The libraries 914 can include system libraries 930 (e.g., C standard library) that provide functions such as memory allocation functions, string manipulation functions, mathematic functions, and the like. In addition, the libraries 914 can include API libraries 932 such as media libraries (e.g., libraries to support presentation and manipulation of various media formats such as Moving Picture Experts Group-4 (MPEG4), Advanced Video Coding (H.264 or AVC), Moving Picture Experts Group Layer-3 (MP3), Advanced Audio Coding (AAC), Adaptive Multi-Rate (AMR) audio codec, Joint Photographic Experts Group (PEG or JPG), or Portable Network Graphics (PNG)), graphics libraries (e.g., an OpenGL framework used to render in two dimensions (2D) and three dimensions (3D) in a graphic content on a display), database libraries (e.g., SQLite to provide various relational database functions), web libraries (e.g., WebKit to provide web browsing functionality), and the like. The libraries 914 can also include a wide variety of other libraries 934 to provide many other APIs to the applications 918.

The frameworks 916 provide a common high-level infrastructure that is used by the applications 918. For example, the frameworks 916 provide various graphical user interface (GUI) functions, high-level resource management, and high-level location services. The frameworks 916 can provide a broad spectrum of other APIs that can be used by the applications 918, some of which may be specific to a particular operating system or platform.

In an example, the applications 918 may include a home application 936, a contacts application 938, a browser application 940, a book reader application 942, a location application 944, a media application 946, a messaging application 948, a game application 950, and a broad assortment of other applications such as a third-party application 952. The applications 918 are programs that execute functions defined in the programs. Various programming languages can be employed to create one or more of the applications 918, structured in a variety of manners, such as object-oriented programming languages (e.g., Objective-C, Java, or C++) or procedural programming languages (e.g., C or assembly language). In a specific example, the third-party application 952 (e.g., an application developed using the ANDROID™ or IOS™ software development kit (SDK) by an entity other than the vendor of the particular platform) may be mobile software running on a mobile operating system such as IOS™, ANDRDID™, WINDOWS® Phone, or another mobile operating system. In this example, the third-party application 952 can invoke the API calls 920 provided by the operating system 912 to facilitate functionalities described herein.

### CONCLUSION

Thus, the interaction system 100 as described herein provides different indications that video recording is active (e.g., in response to a press-and-hold gesture of a shutter button). For example, prior to the press-and-hold gesture, the interaction client 104 presents a user interface (e.g., a camera interface) with image data and a shutter button. Upon detecting the press-and-hold gesture, the interaction client 104 replaces a first set of interface elements within the user interface with a second set of interface elements. The first set of interface elements includes a profile button, a search button, a memories button, a carousel interface launch button, a toolbar or a tab bar. The second set of interface elements includes a border for the camera viewport, an animated icon (e.g., a company logo) within the border, a hands-free icon (e.g., a lock icon) for hands-free video recording, and a flip camera icon for switching between a front and rear-facing cameras while recording. In addition, the interaction client 104 updates the appearance of the shutter button by filling the shutter button with a predefined color (e.g., yellow), and including a progress indicator which appears to circle around the shutter button.

By virtue of providing different indications that video recording is active, the interaction client 104 provides increased interactive feedback and/or progress associated with video recording. Without providing such indications, the status and progress of video recording may be difficult to determine. Thus, the interaction client 104 facilitates the capturing of videos, thereby saving time for the user (e.g., by reducing the number of retakes), and reducing computational resources/processing, power for the interaction system 100.

### Glossary

“Carrier signal” refers, for example, to any intangible medium that is capable of storing, encoding, or carrying instructions for execution by the machine and includes digital or analog communications signals or other intangible media to facilitate communication of such instructions. Instructions may be transmitted or received over a network using a transmission medium via a network interface device.

“Client device” refers, for example, to any machine that interfaces to a communications network to obtain resources from one or more server systems or other client devices. A client device may be, but is not limited to, a mobile phone, desktop computer, laptop, portable digital assistants (PDAs), smartphones, tablets, ultrabooks, netbooks, laptops, multi-processor systems, microprocessor-based or programmable consumer electronics, game consoles, set-top boxes, or any other communication device that a user may use to access a network.

“Communication network” refers, for example, to one or more portions of a network that may be an ad hoc network, an intranet, an extranet, a virtual private network (VPN), a local area network (LAN), a wireless LAN (WLAN), a wide area network (WAN), a wireless WAN (WWAN), a metropolitan area network (MAN), the Internet, a portion of the Internet, a portion of the Public Switched Telephone Network (PSTN)), a plain old telephone service (POTS) network, a cellular telephone network, a wireless network, a network, another type of network, or a combination of two or more such networks. For example, a network or a portion of a network may include a wireless or cellular network, and the coupling may be a Code Division Multiple Access (CDMA) connection, a Global System for Mobile communications (GSM) connection, or other types of cellular or wireless coupling. In this example, the coupling may implement any of a variety of types of data transfer technology, such as Single Carrier Radio Transmission Technology (1×RTT), Evolution-Data Optimized (EVDO) technology, General Packet Radio Service (GPRS) technology, Enhanced Data rates for GSM Evolution (EDGE) technology, third Generation Partnership Project (3GPP) including 3G, fourth-generation wireless (4G) networks, Universal Mobile Telecommunications System (UMTS), High Speed Packet Access (HSPA), Worldwide Interoperability for Microwave Access (WiMAX), Long Term Evolution (LTE) standard, others defined by various standard-setting organizations, other long-range protocols, or other data transfer technology.

“Component” refers, for example, to a device, physical entity, or logic having boundaries defined by function or subroutine calls, branch points, APIs. or other technologies that provide for the partitioning or modularization of particular processing or control functions. Components may be combined via their interfaces with other components to carry out a machine process. A component may be a packaged functional hardware unit designed for use with other components and a part of a program that usually performs a particular function of related functions. Components may constitute either software components (e.g., code embodied on a machine-readable medium) or hardware components. A “hardware component” is a tangible unit capable of performing certain operations and may be configured or arranged in a certain physical manner. In various examples, one or more computer systems (e.g., a standalone computer system, a client computer system, or a server computer system) or one or more hardware components of a computer system (e.g., a processor or a group of processors) may be configured by software (e.g., an application or application portion) as a hardware component that operates to perform certain operations as described herein. A hardware component may also be implemented mechanically, electronically, or any suitable combination thereof. For example, a hardware component may include dedicated circuitry or logic that is permanently configured to perform certain operations. A hardware component may be a special-purpose processor, such as a field-programmable gate array (FPGA) or an application-specific integrated circuit (ASIC). A hardware component may also include programmable logic or circuitry that is temporarily configured by software to perform certain operations. For example, a hardware component may include software executed by a general-purpose processor or other programmable processors. Once configured by such software, hardware components become specific machines (or specific components of a machine) uniquely tailored to perform the configured functions and are no longer general-purpose processors. It will be appreciated that the decision to implement a hardware component mechanically, in dedicated and permanently configured circuitry, or in temporarily configured circuitry (e.g., configured by software), may be driven by cost and time considerations. Accordingly, the phrase “hardware component” (or “hardware-implemented component”) should be understood to encompass a tangible entity, be that an entity that is physically constructed, permanently configured (e.g., hardwired), or temporarily configured (e.g., programmed) to operate in a certain manner or to perform certain operations described herein. Considering examples in which hardware components are temporarily configured (e.g., programmed), each of the hardware components need not be configured or instantiated at any one instance in time. For example, where a hardware component comprises a general-purpose processor configured by software to become a special-purpose processor, the general-purpose processor may be configured as respectively different special-purpose processors e.g., comprising different hardware components) at different times. Software accordingly configures a particular processor or processors, for example, to constitute a particular hardware component at one instance of time and to constitute a different hardware component at a different instance of time. Hardware components can provide information to, and receive information from, other hardware components. Accordingly, the described hardware components may be regarded as being communicatively coupled. Where multiple hardware components exist contemporaneously, communications may be achieved through signal transmission (e.g., over appropriate circuits and buses) between or among two or more of the hardware components. In examples in which multiple hardware components are configured or instantiated at different times, communications between such hardware components may be achieved, for example, through the storage and retrieval of information in memory structures to which the multiple hardware components have access. For example, one hardware component may perform an operation and store the output of that operation in a memory device to which it is communicatively coupled. A further hardware component may then, at a later time, access the memory device to retrieve and process the stored output. Hardware components may also initiate communications with input or output devices, and can operate on a resource (e.g., a collection of information). The various operations of example methods described herein may be performed, at least partially, by one or more processors that are temporarily configured (e.g., by software) or permanently configured to perform the relevant operations. Whether temporarily or permanently configured, such processors may constitute processor-implemented components that operate to perform one or more operations or functions described herein. As used herein. “processor-implemented component” refers to a hardware component implemented using one or more processors. Similarly, the methods described herein may be at least partially processor-implemented, with a particular processor or processors being an example of hardware. For example, at least some of the operations of a method may be performed by one or more processors or processor-implemented components. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an API). The performance of certain of the operations may be distributed among the processors, not only residing within a single machine, but deployed across a number of machines. In some examples, the processors or processor-implemented components may be located in a single geographic location (e.g., within a home environment, an office environment, or a server farm). In other examples, the processors or processor-implemented components may be distributed across a number of geographic locations.

“Computer-readable storage medium” refers, for example, to both machine-storage media and transmission media. Thus, the terms include both storage devices/media and carrier waves/modulated data signals. The terms “machine-readable medium.” “computer-readable medium” and “device-readable medium” mean the same thing and may be used interchangeably in this disclosure.

“Machine storage medium” refers, for example, to a single or multiple storage devices and media (e.g., a centralized or distributed database, and associated caches and servers) that store executable instructions, routines and data. The term shall accordingly be taken to include, but not be limited to, solid-state memories, and optical and magnetic media, including memory internal or external to processors. Specific examples of machine-storage media, computer-storage media and device-storage media include non-volatile memory, including by way of example semiconductor memory devices, e.g., erasable programmable read-only memory (EPROM), electrically erasable programmable read-only memory (EEPROM), FPGA, and flash memory devices; magnetic disks such as internal hard disks and removable disks; magneto-optical disks; and CD-ROM and DVD-ROM disks The terms “machine-storage medium,” “device-storage medium,” “computer-storage medium” mean the same thing and may be used interchangeably in this disclosure. The terms “machine-storage media,” “computer-storage media,” and “device-storage media” specifically exclude carrier waves, modulated data signals, and other such media, at least some of which are covered under the term “signal medium.”

“Non-transitory computer-readable storage medium” refers, for example, to a tangible medium that is capable of storing, encoding, or carrying the instructions for execution by a machine.

“Signal medium” refers, for example, to any intangible medium that is capable of storing, encoding, or carrying the instructions for execution by a machine and includes digital or analog communications signals or other intangible media to facilitate communication of software or data. The term “signal medium” shall be taken to include any form of a modulated data signal, carrier wave, and so forth. The term “modulated data signal” means a signal that has one or more of its characteristics set or changed in such a matter as to encode information in the signal. The terms “transmission medium” and “signal medium” mean the same thing and may be used interchangeably in this disclosure.

“User device” refers, for example, to a device accessed, controlled or owned by a user and with which the user interacts perform an action, or an interaction with other users or computer systems.

What is claimed is:

1. A system comprising:
a processor; and
a memory storing instructions that, when executed by the processor, configure the processor to perform operations comprising:
providing a floating point model to an automatic quantization library, the floating point model being configured to represent a neural network, and the automatic quantization library being configured to generate a first quantized model based on the floating point model;
providing a function to the automatic quantization library, the function being configured to run a forward pass on a given dataset for the floating point model;
causing the automatic quantization library to generate the first quantized model based on the floating point model;
causing the automatic quantization library to calibrate the first quantized model by running the first quantized model on the function; and
converting the calibrated first quantized model to a second quantized model.

2. The system of claim 1, the operations further comprising:
providing the second quantized model to a client device, wherein the second quantized model is configured to represent the neural network and to be accessible by an application running on the client device.

3. The system of claim 2, wherein the automatic quantization library is usable by developers to quantize floating point models representing respective neural networks, for deployment to client devices running the application.

4. The system of claim 1, the operations further comprising, prior to converting the calibrated first quantized model to the second quantized model:
exporting the calibrated first quantized model to an open neural network exchange format,
wherein converting the calibrated first quantized model to the second quantized model is based on the open neural network exchange format.

5. The system of claim 1, wherein each of the floating point model and the first quantized model corresponds to a 32-bit floating point model.

6. The system of claim 5, wherein the second quantized model corresponds to an 8-bit quantized model.

7. The system of claim 5, wherein the calibrated first quantized model corresponds to a 32-bit floating point model with quantization statistics.

8. The system of claim 1, wherein the automatic quantization library is configured to:
generate a computational graph based on the floating point model;
for each node in the computational graph,
extract a layer type for the node,
match the layer type to a quantized layer type supported by the automatic quantization library, and
replace the node with a quantized node corresponding to the quantized layer type; and
provide the first quantized model as output based on replacing the nodes with the quantized nodes.

9. A method, comprising:
providing a floating point model to an automatic quantization library, the floating point model being configured to represent a neural network, and the automatic quantization library being configured to generate a first quantized model based on the floating point model;
providing a function to the automatic quantization library, the function being configured to run a forward pass on a given dataset for the floating point model;
causing the automatic quantization library to generate the first quantized model based on the floating point model;
causing the automatic quantization library to calibrate the first quantized model by running the first quantized model on the function; and
converting the calibrated first quantized model to a second quantized model.

10. The method of claim 9, further comprising:
providing the second quantized model to a client device, wherein the second quantized model is configured to represent the neural network and to be accessible by an application running on the client device.

11. The method of claim 10, wherein the automatic quantization library is usable by developers to quantize floating point models representing respective neural networks, for deployment to client devices running the application.

12. The method of claim 9, further comprising, prior to converting the calibrated first quantized model to the second quantized model:
exporting the calibrated first quantized model to an open neural network exchange format,
wherein converting the calibrated first quantized model to the second quantized model is based on the open neural network exchange format.

13. The method of claim 9, wherein each of the floating point model and the first quantized model corresponds to a 32-bit floating point model.

14. The method of claim 13, wherein the second quantized model corresponds to an 8-bit quantized model.

15. The method of claim 13, wherein the calibrated first quantized model corresponds to a 32-bit floating point model with quantization statistics.

16. The method of claim 9, wherein the automatic quantization library is configured to:
generate a computational graph based on the floating point model;
for each node in the computational graph,
extract a layer type for the node,
match the layer type to a quantized layer type supported by the automatic quantization library, and
replace the node with a quantized node corresponding to the quantized layer type; and
provide the first quantized model as output based on replacing the nodes with the quantized nodes.

17. A non-transitory computer-readable storage medium, the computer-readable storage medium including instructions that when executed by a computer, cause the computer to perform operations comprising:
providing a floating point model to an automatic quantization library, the floating point model being configured to represent a neural network, and the automatic quantization library being configured to generate a first quantized model based on the floating point model;
providing a function to the automatic quantization library, the function being configured to run a forward pass on a given dataset for the floating point model;
causing the automatic quantization library to generate the first quantized model based on the floating point model;
causing the automatic quantization library to calibrate the first quantized model by running the first quantized model on the function; and
converting the calibrated first quantized model to a second quantized model.

18. The non-transitory computer-readable storage medium of claim 17, the operations further comprising:
providing the second quantized model to a client device, wherein the second quantized model is configured to represent the neural network and to be accessible by an application running on the client device.

19. The non-transitory computer-readable storage medium of claim 18, wherein the automatic quantization library is usable by developers to quantize floating point models representing respective neural networks, for deployment to client devices running the application.

20. The non-transitory computer-readable storage medium of claim 17, the operations further comprising, prior to converting the calibrated first quantized model to the second quantized model:
exporting the calibrated first quantized model to an open neural network exchange format,
wherein converting the calibrated first quantized model to the second quantized model is based on the open neural network exchange format.
